(19) United States
(12) Patent Application Publication
(10) Pub. No.: US 2007/0212808 A1
(43) Pub. Date: Sep. 13, 2007

(54) Method of selective removal of organophosphonic acid molecules from their self-assembled monolayer on Si substrates

(76) Inventors: Heng-Yong Nie, London (CA); N. Stewart McIntyre, London (CA); Leo Woon Ming Lau, London (CA)

Correspondence Address: Ralph A. Dowell of DOWELL & DOWELL P.C., 2111 Eisenhower Ave, Suite 406, Alexandria, VA, 22314, US

(21) Appl. No.: 11/716,013

(22) Filed: Mar. 9, 2007

Related U.S. Application Data
(60) Provisional application No. 60/780,346, filed on Mar. 9, 2006.

(51) Int. Cl. H01L 51/40

(52) U.S. Cl. 438/99

(57) ABSTRACT

A scanning probe based method to selectively remove self-assembled organic molecules from their self-assembled monolayer (SAM) prepared on a conducting/semiconducting substrate having a hydrophilic surface. This technique involves the use of a conductive probe tip scanning a SAM with a thickness of not more than a few nanometers under an electric field applied by the scanning tip with a field strength of about 10⁹ V/m between the tip and the surface of the conducting/semiconducting substrate. The patterned SAM can be used a device mould for the development of a nano-lithography technology or a device element in the fabrication of a nano-device. The present invention accommodates the trend of ever-decreasing size of devices.

### CROSS REFERENCE TO RELATED APPLICATION

This patent is related to, and claims priority from, U.S. provisional patent application Ser. No. 60/780,346 filed on Mar. 9, 2006, entitled METHOD OF SELECTIVE REMOVAL OF ORGANOPHOSPHONIC ACID MOLECULES FROM THEIR COMPLETE SELF-ASSEMBLED MONOLAYER ON Si SUBSTRATES, filed in English, which is incorporated herein by reference in its entirety.

### FIELD OF THE INVENTION

The present invention relates generally to a method for the selective removal of self-assembled monolayer molecules from their self-assembled monolayer on a substrate, and more particularly the present invention relates to a device fabrication method for patterning a sheet of self-assembled monolayer molecules into a two-dimensional mesa structure by selective removal self-assembly monolayer molecules from their self-assembled monolayer on a substrate.

### BACKGROUND OF THE INVENTION

In order to achieve the goal of miniaturizing integrated circuits down to the smallest size regimes, fabrication techniques must be developed which allow the construction of conducting, semiconducting and insulating device elements in a mesa structure with features as small as a few nanometers. In the current integrated circuit fabrication, the three-dimensional mesa structure of a device is built with a layer-by-layer approach. Typically a lithography method is used to delineate a two-dimensional device pattern. In this method, a film of organic molecules called photoresist, typically with a film thickness measured in micrometers, are spin-cast on a wafer and then patterned by polymerizing the organic molecules in selective areas with an irradiation source in conjunction with a mask. The pattern photoresist film is then used a mould to make a conducting, semiconducting or insulating replica of the device pattern. This process of constructing one layer of the device is repeated for the completion of the final three-dimensional device structure. There are several constraints limiting how small a device can be made, constraints which can be overcome by (a) the development of new methods for making the mould so that the hole features of the mould can be as small as a few nanometers; and (b) the development of new methods for making the mould so that the height of the hole features of the mould or the thickness of the mould can be as small as a few nanometers. The former requirement has driven the research of X-ray and electron-beam lithography, and the latter requirement can be addressed by adopting the approach of using a single layer of molecules as the body of the mould.

In addition to improving the lithography method for making mould patterns with feature size down to a few nanometers, researchers have also been looking into novel techniques for directly writing a pattern of conducting, semiconducting and insulating device elements with a feature size in a nanometer scale. Scanning probe based nanolithorgraphic methods have also been discussed in references 1-4. As mentioned above, thinner moulds are needed to accommodate the trend of ever-decreasing size of electronic devices and thus organic self-assembling molecules (SAMs) are considered to be a promising candidate for building moulds with a thickness down to 1-2 nanometers, see reference 5. For example, scanning probes have been previously used for direct writing of nanoscale features onto a substrate by scanning a positively biased probe tip across the surface (see references 6-10). When such a tip makes a contact with a substrate placed in air, a water bridge formed between them, which behaves as an electrochemical cell when electric bias potential is applied.

It has been established that such an electrochemical process results in oxidation of the sample surface, see references 6 to 10. When applying a positive bias to a Si substrate, the surface of the sample under the contact with the tip may be oxidized depending on the relative humidity and strength of the electric field. This electric field-induced anodic oxidation of the sample surface is electrochemical in nature, see reference 8, and it has been used for patterning protruding features on the substrates for device fabrication, see references 6, 7 and 9. However, this method does not teach a process of removing molecules in the scanned area, which is desirable in both the fabrication of a mould and a device element in a nanometer scale.

Sugimura et al applied the method of using a negatively biased scanning tip to trimethylsilyl, see references 5, 11 or octadecyltrimethoxysilane, see reference 12, monolayers prepared on a Si substrate using chemical vapor deposition. They found that the scanned lines became protruded, which was explained, see references 5,11,12, as the result of and oxidation of silicon substrate (see references 6-10) of the Si substrate. Similarly, Maoz et al applied negative bias to a conductive probe tip while scanning a silane monolayer prepared on a Si substrate to only oxidize the outermost hydrophobic group (vinyl or methyl) so that the scanned areas could be converted to carboxylic acid functional groups, on which they deposited another silane monolayer, see references 13, 14. Once again, these methods do not teach a process of removing molecules in the scanned area.

Recently, an “inked” tip has been used to deliver organic molecules onto a substrate in a dip-pen fashion (see reference 15). The “ink” molecules are transferred onto the substrate through capillary meniscus induced by water films condensed on the surface. More recently, it has been shown that a probe tip coated with organic molecules, octadecylphosphonic acid (OPA), can be used to deliver the molecules onto mica surface by heating the tip at temperatures over the melting point (˜100° C.) of OPA (see reference 16).

Lithography using a scanning probe tip to mechanically remove self-assembled monolayer (SAM) on a substrate has been discussed (see references 17 and 18). This method is complementary with those described above, which create protruding features on a substrate. Although mechanically removing a covering layer is possible under certain applied forces, some of the ploughed molecules will pile up along the perimeter of the scanned area. Further, undesirable mechanical interactions between the tip and the surface of the covering layer, interactions which include lubrication present on the film surface, especially that of SAMs (see reference 19) are prone to complicate the application of this method.

Removing molecules in the scanned area with the scanning probe approach of making devices in a nanometer scale because the hole features in the mould made by removing molecules in the scanned area can be as small as the size of the tip which can be atomically sharp. By filling the hole features with conducting, semiconducting or insulating atoms and molecules, one can then make a device element with a feature size in a nanometer scale. The present invention is a method of using a positively-biased probe tip to selectively remove organic molecules from their SAMs on a substrate.

There are at least two important applications for the present invention. The first application is to make a device mould with a nanometer scale in both the hole size and the mould thickness for the fabrication of devices in a nanometer scale. The second application is to use the patterned self-assembled monolayer as a conducting, semiconducting or insulating device element with a feature size down to the nanometer scale.

### SUMMARY OF THE INVENTION

The present invention provides a lithographic technique to allow one to pattern a surface down to molecular dimensions. The present invention provides a method for the selective removal of self-assembled monolayer molecules from their self-assembled monolayer on a substrate, which can be used as a device fabrication method for patterning a sheet of self-assembled monolayer molecules into a two-dimensional mesa structure by selective removal of self-assembly monolayer molecules from their self-assembled monolayer on a substrate. The present invention can be used as a lithography method by using the patterned self-assembled monolayer as a mould for the fabrication of conducting, semiconducting or insulating replicas of the pattern. The present invention can also be used directly for device construction by retaining the patterned self-assembled layer as a conducting, semiconducting or insulating device element.
In one aspect the present invention provides a method of selectively removing organic molecules from a self-assembled film of such organic molecules on a substrate having a hydrophilic surface, comprising:

applying a first bias potential to a substrate having a hydrophilic surface and a self-assembled film of organic molecules located on the hydrophilic surface, the organic molecules having a polar headgroup attached to an aromatic or aliphatic hydrocarbon structure; and

applying a second bias potential to a conductive probe tip wherein said second bias potential is more positive than said first bias potential such that a potential difference between said first and second potentials is greater than a threshold voltage above which organic molecules adjacent to the conductive probe tip are removed.

In another aspect of the present invention there is provided a method of patterning a substrate having a hydrophilic surface having a self-assembled film of organic molecules on said hydrophilic surface, comprising the steps of:

a) treating a surface of a substrate having a hydrophilic surface to remove impurities therefrom; and

b) exposing the hydrophilic surface to a fluid comprising a mixture of organic molecules which can self-assemble on the hydrophilic surface and hydrophobic molecules, the organic molecules being comprised of a polar headgroup attached to an aromatic or aliphatic hydrocarbon structure;

c) applying a first bias potential to the substrate;

d) applying a second bias potential to a conductive probe tip wherein said second bias potential is more positive than said first bias potential such that a potential difference between said first and second potentials is greater than a threshold voltage above which organic molecules are removed below the conductive probe tip; and

e) scanning said conductive probe in a pattern over the surface of the substrate in close proximity to the surface leaving behind said pattern of removed organic molecules.

A further understanding of the functional and advantageous aspects of the invention can be realized by reference to the following detailed description and drawings, and from the claims.

### BRIEF DESCRIPTION OF THE DRAWINGS

The following is a description, by way of example only, of embodiments of an apparatus for dispensing powder coatings constructed in accordance with the present invention, reference being had to the accompanying drawings, in which:

FIG. 1(a) shows illustration of removal of OPA molecules from their SAM by applying a positive bias voltage to the probe tip that contacts with the OPA SAM prepared on a Si substrate, in which the OPA headgroup and tail are represented by a circle and a zigzag line, respectively. The inventors use OPA as a model SAM molecule in this example just because of the convenience and ready availability of OPA. The inventors believe, without being bound by any theory, that the OPA headgroups are negatively charged on the Si substrate. FIG. 1(b) shows a topographic image for the removal of OPA SAMs on a Si substrate by applying a positive bias (6 V) to the tip scanning in the y-direction at a fixed x-position in air under a relative humidity of 45%, the scan size is 1.7 μm. Also shown in FIG. 1(b) is a profile isolated from the image indicated by the insert line.

FIG. 2 shows (a) topographic and (b) lateral force images for the OPA SAMs on a Si substrate by applying a negative bias (−20 V) to the tip scanning in the y-direction at a fixed x-position in air under a relative humidity of 45%, the scan area is 4 μm. A profile isolated from the image indicated by the insert line is shown below the image.

FIG. 3 shows a topographic image for negatively- and positively-biased-tip schemes, which show very different results. Applying a negative bias of −10 V to the tip in air under a relative humidity of 30% results in a formation of protrusions. Only applying a positive bias of 10 V to the tip in air under a relative humidity of 30% results in a removal of OPA molecules from the SAM. Note that there are pits in the OPA SAM. The scan size is 2 μm and the height scale is 2.5 nm.

### DETAILED DESCRIPTION OF THE INVENTION

Generally speaking, the systems described herein are directed to a method for patterning a surface by selective removal self-assembled monolayer molecules such as octadecylphosphonic acid (OPA) molecules from their self-assembled monolayers (SAMs) on substrates. As required, embodiments of the present invention are disclosed herein. However, the disclosed embodiments are merely exemplary, and it should be understood that the invention may be embodied in many various and alternative forms. The Figures are not to scale and some features may be exaggerated or minimized to show details of particular elements while related elements may have been eliminated to prevent obscuring novel aspects. Therefore, specific structural and functional details disclosed herein are not to be interpreted as limiting but merely as a basis for the claims and as a representative basis for teaching one skilled in the art to variously employ the present invention. For purposes of teaching and not limitation, the illustrated embodiments are directed to a method for patterning a surface of a substrate by selective removal SAM molecules such as octadecylphosphonic acid molecules from their SAMs on the substrate.

As used herein, the term “about”, when used in conjunction with ranges of dimensions, temperatures or other physical properties or characteristics is meant to cover slight variations that may exist in the upper and lower limits of the ranges of for example voltage ranges or thicknesses of layers so as to not exclude embodiments where on average most of the dimensions are satisfied but where statistically dimensions may exist outside this region.

As used herein, the term “self-assembled monolayers (SAMs)” means two-dimensional ordered and oriented molecular assemblies formed by spontaneous adsorption of amphiphilic molecules on a substrate. Usually, there are two interactions that are critical for the formation of SAMs; 1) adequate interaction between the hydrophilic moiety of the molecule and the substrate and 2) a balanced force between the hydrophobic molecular chains.

As used herein, the term “substrate with a hydrophilic surface” means any substrate having a high surface energy so that water spreads out on the surface.

As used herein, the phrase “functionalizing the molecules forming the self-assembled monolayer with pre-selected moieties” means addition of selected functional groups on the organic, hydrophobic end of the amphiphilic molecules, using chemical solutions, gas phase treatment using reactive chemicals or plasma or UV-ozone treatment.

The inventors have developed a method to deliver a complete 100% coverage OPA SAM onto Si substrates and various other oxide surfaces using a process combining a hydrophobic solvent and spin-coating as disclosed in WO 2005/016559 A1 (now copending U.S. national phase patent application Ser. No. 10/568,619 which is incorporated herein by reference in its entirety) and reference 20. This expands the applications of OPA SAMs as they had been mainly investigated on a mica substrate and no complete coverage had been available using conventional methods.

In the present invention, it has been discovered that by scanning a positively biased conductive tip across an SAM covered surface, it is possible to selectively remove SAM molecules from their SAMs on the Si substrate without anodizing the exposed Si substrate. As demonstrated in the examples presented hereinafter in this description, when the electric potential bias between the conductive tip and the sample ranges from 4 to 20 V (relative to the tip) it is possible to obtain controlled and selective removal of OPA molecules. However, other values of bias are contemplated to work as long as the electric energy provided by the bias is such that is enough to move the molecules. The optimal value of bias is affected by the nature of the molecules, the nature of the substrate, the nature of the tip-film separation, and the nature of the environmental conditions such as humidity. The present method thus does not involve the friction/lubrication issues presented by the SAM surface. The thickness of the SAM is on the order of 2 nm, much thinner than that of the currently used photoresist. As mentioned above, thinner device mounds are needed to accommodate the trend of ever-decreasing size of electronic devices and thus organic self-assembling molecules (SAMs) are considered to be a promising candidate. The combination of use of a SAM on a Si substrate and the positively-biased-tip scheme for selective removal of SAM molecules disclosed herein provides a novel route for nanolithography and direct writing of device elements in a nanometer scale.

While the above description describes positively biasing the scanning probe tip and grounding the substrate, it will be appreciated that the scanning probe tip may be held at electrical ground potential and the substrate held at a negative electrical potential. The method works as long as the potential difference between the tip and the substrate is positive (i.e., Vₜᵢₚ−V_{substrate}>0) and exceeds the threshold voltage required to remove the organic molecules. It will be appreciated by those skilled in the art that the threshold voltage will depend on many factors such as molecular length, interaction strength between the polar molecular headgroup and the substrate, the nature of the substrate, humidity, conductivity of the probe tip, contact force of the tip. The potential difference between the scanning probe and the substrate should produce an electric field applied by the scanning tip with a field strength ranging from 10⁸ to 10¹⁰ V/m across the monolayer film. A useful field strength is about 10⁹ V/m across the monolayer film.

A PSIA XE-100 Atomic Force Microscopy (AFM) was used to explore the lithographic application for an OPA SAM spin-coated on a Si substrate. Cantilevers with a spring constant of 0.1-0.3 N/m. AFM images were obtained in contact mode and the imaging force was nominally a couple of nanonewtons. The conductive probe tip coated by Ti—Pt had a radius of ˜50 nm. The bias was applied between the tip and the sample stage, on which the Si substrate was placed. The lithography was done by scanning the biased conductive tip over the OPA/Si sample. Then the bias was set to zero and the same tip was used to image the patterning.

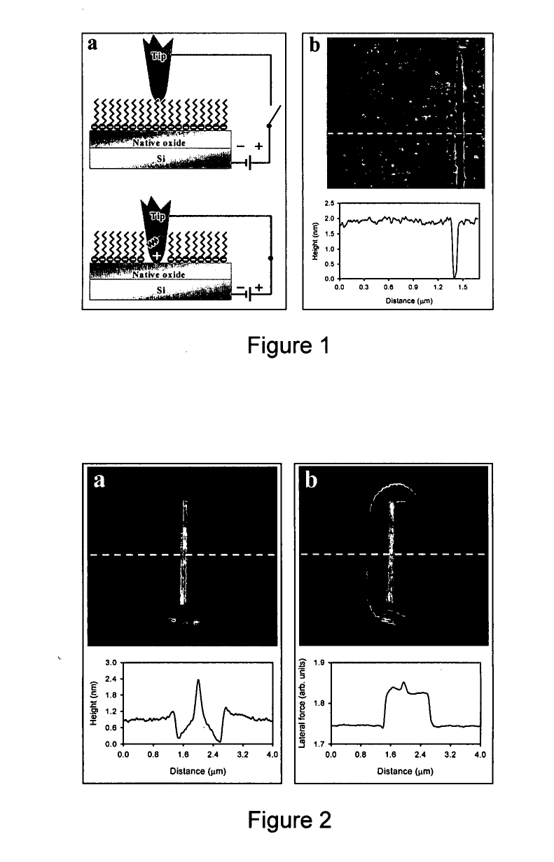

A schematic illustration is shown in FIG. 1(a) for the configuration of the probe tip and the OPA/SiO₂/Si sample system, in which the bias polarity is referred to the tip. The conductive probe tip may simply be a metal needle such as a scanning tunneling tip or a silicon cantilever tip (for AFM). FIG. 1(a) shows illustration of removal of OPA molecules from their SAM by applying a positive bias voltage to the probe tip that contacts with the OPA SAM prepared on a Si substrate, in which the OPA headgroup and tail are represented by a circle and a zigzag line, respectively. Without being bound by any theory, the inventors believe the OPA headgroups are negatively charged on the Si substrate. FIG. 1(a) shows that when a sufficient positive bias applied to the tip, OPA molecules may be removed.

FIG. 1(b) shows a topographic image for the removal of OPA SAMs on a Si substrate by applying a positive bias (6 V) to the tip scanning in the y-direction at a fixed x-position in air under a relative humidity of 45%, the scan size is 1.7 μm and the height scale is 2.5 nm. Also shown in FIG. 1(b) is a profile isolated from the image indicated by the insert line. More particularly, FIG. 1(b) is topographic image for the patterning of the OPA SAM by applying a positive bias to the tip while scanning the tip 2 μm long a couple of times in the y-direction at a fixed x-direction at a scan speed of 1 Hz. From FIG. 1(b), the depth and width of the inscribed line are estimated to be ˜1.8 and ˜70 nm, respectively. It is clear that the positive bias applied to the tip resulted in a complete removal of the OPA molecules from the Si substrate within the region scanned by the conductive tip. The inventors also applied 1, 2, and 4 V to the tip, but nothing happed under these lower bias voltages. This suggests that there exist a threshold bias voltage for OPA molecular removal. It was found that the threshold voltage was 5-7 V under the relative humidity over 40%. The linewidth of the scanned area with molecules removed by the positively biased tip shown in this example has not been optimized. Clearly the minimum linewidth is only limited by the technology of making atomically sharp tips and the optimization of the scanning conditions.

Without limiting the present invention to any particular applications mentioned herein, there are at least two applications for this method of selectively removing molecules from their SAMs on a substrate. The first one is nanolithography, that is, one can fabricate a device mould with both the hole features and mould thickness down to the nanometer size scale. The device mould can then be used for the formation of a conducting, semiconducting or insulating replica of the mould by the deposition of metallic, semiconducting, or insulating materials. If necessary, one can process the mould by polymerization to enhance the stability of the mould.

The second application of this method is to construct electronic devices or chemical sensors with the patterned SAMs as active elements. For example, one can first fabricate a pattern of an n-type semiconducting organic molecular monolayer followed by spin-coating a p-type semiconducting organic molecular monolayer. The second molecular monolayer can be formed in the hole features of the first patterned SAM layer, using a process disclosed in WO 2005/016559 A1 (now copending U.S. national phase patent application Ser. No. 10/568,619) and reference 20. This way, nanoscale p-n junctions can be fabricated on a substrate, which are the basic building block in electronic and optoelectronic devices.

When a negative bias was applied to the tip while scanning the tip on the OPA SAM surface, a crater-like rather than a line-like feature was observed, suggesting a long-distance modification of the OPA molecules. FIG. 2(a) shows topographic and FIG. 2(b) shows lateral force images for the crater formation on OPA SAMs on a Si substrate by applying a negative bias (−20 V) to the tip scanning 2 μm long in the y-direction at a fixed x-direction in air under a relative humidity of45%, the scan area is 4 μm and the height scale for (a) is 3 nm. The crater has a depth of ˜1.0 nm and its width appears to be 1.3 μm. Seen at the center of the crater is a ridge raising 1.5 nm from the OPA surface. This is clearly due to anodic oxidation of the Si substrate. The inventors have confirmed that with a smaller bias (e.g., −7 V), a crater was still created but the oxidation of the Si substrate was much less so that only a faint raise could be seen.

From the lateral force image, FIG. 2(b), one sees a huge increase in lateral force within the crater. This suggests that the crater surface is highly hydrophilic. It is thus inferred that the OPA molecules collapsed and may be oxidized along with the underlying Si substrate, dependent on the magnitude of negative bias voltage applied to the tip.

It should be emphasized here, therefore, that although a negatively-biased tip can make some changes of the SAM and the substrate, including the formation of a crater in the scanned area, there are several undesirable effects in this approach. First, the crater size is much larger than the tip size. Second, protrusions due to anodization are formed in the scanned area. Hence, the positively-biased-tip configuration disclosed herein is very advantageous in avoiding these problems.

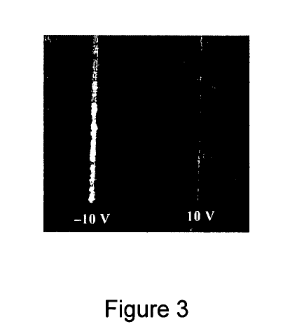

FIG. 3 shows a topographic image for negatively- and positively-biased-tip schemes, which further illustrates the different results of these two configurations. Applying a negative bias of −10 V to the tip in air under a relative humidity of 30% results in the formation of protrusion. Only applying a positive bias of 10 V to the tip in air under a relative humidity of 30% results in the removal of OPA molecules from the SAM.

As shown in FIG. 3, at a relative humidity of ˜30%, the positively-biased-tip scheme results in the removal of OPA, resulting in line of ˜40 nm wide. Also shown in FIG. 3, the inventors have confirmed that at lower relative humidity (e.g., 30%) a crater in the SAM cannot be formed in the scanned area under the negatively-biased-tip scheme. Instead, only a protrusion is seen after scanning under this scheme, which may be similar to what has been seen on the system of silane on Si discussed in references 5, 11 and 12. In contrast, with the positively-biased-tip configuration disclosed herein, the removal of OPA molecules still works. Therefore, it is important to adopt the positively-biased-tip scheme for selective removal of the SAM molecules in the scanned area. Not wanting to be bound by any particular theory as why the OPA molecules are removed, the inventors contemplate that the OPA headgroup has an effective negative charge. Therefore, under the positively-biased-tip scheme, the OPA molecules are repelled by the Si surface and pulled out by the tip, thus resulting in well-defined lines presenting the removal of OPA molecules under the influence of the electric field between the tip and the sample surface. Therefore, as long as the OPA headgroup is negatively charged or polarized for whatever reason, this method provides a way of selectively patterning a surface on a molecular level.

Thus, the present invention provides a method of patterning a surface of a substrate by forming SAMs on the surface and then using the aforementioned technique to selectively remove the SAM molecules in any desired pattern, regular or not by simply controlling the position of the probe. The method for producing the full coverage of OPA molecules is disclosed in copending U.S. national phase patent application Ser. No. 10/568,619 which is incorporated herein by reference in its entirety. Briefly, the method of producing the full coverage monolayer on a substrate having a hydrophilic surface by pre-treating the hydrophilic surface to remove impurities therefrom followed by exposure of the hydrophilic surface to a fluid comprising a mixture of molecules which can self-assemble on the hydrophilic surface and hydrophobic molecules for a sufficient length of time so that the molecules which can self-assemble on the hydrophilic surface form a complete self-assembled monolayer. The organic molecules which can self-assemble may be any organic molecules having a polar headgroup attached to an aromatic or aliphatic hydrocarbon structure.

The fluid is preferably a liquid dispersion containing the molecules which can self-assemble and the hydrophobic molecules in which the substrate is immersed. A preferred method of spreading the fluid across the surface of the substrate includes spin coating the hydrophilic surface with the liquid dispersion in contact therewith.

Once the monolayer has been produced the probe tip is then run over the surface in a pre-selected scanning pattern, typically under computer control, to selectively remove the SAM molecules to produce the desirable pattern of removed SAM molecules.

In summary, the present invention discloses a scanning probe method to pattern SAMs covering a substrate. This electric-field assisted patterning technique using SAM possesses the potential of applications in lithography as the device mould (patterned SAM) has a thickness on an order of only 2 nm, much thinner than what is available in current photoresist technology, which is a spin-coated polymer film having a much larger thickness. The inventors demonstrated that only the positively-biased-tip scheme allows the conductive probe tip to pull out SAM molecules from their SAMs on a substrate, resulting in a well-defined removal of the molecules that are under the tip-scanned area. The inventors have showed line width for OPA removal to be ˜40 nm. The ultimate resolution of the lines may be determined by the contact area between the tip and the SAM, which may well be much smaller than 40 nm While this invention has been described with respect to selectively removing OPA molecules from a monolayer on a silicon surface, it will be appreciated that the present method may be implemented using any organic molecules having a polar headgroup attached to an aromatic or aliphatic hydrocarbon structure. The polar headgroup binds to the hydrophilic surface.

Thus, in addition to OPA, other organophosphonic acid molecules could be used. These molecules include alkylphosphonic acids and their derivatives, fluorinated alkylphosphonic acids and their derivatives, and the derivatives of the organophosphonic acid molecules. Further examples include organic silane SAMs such as octadecyltrichlorosilane.

The organophosphonic acid molecules may include, but are not limited to, octadecylphosphonic acid and derivatives thereof, dodecylphosphonic acid and derivatives thereof, pyrylphosphonic acid and derivatives thereof, and nonacosafluorohexadecylphosphonic acid and derivatives thereof.

In addition, the terminal end of the aromatic or aliphatic hydrocarbon structure may have functional groups attached thereto to make a functional structure for the patterned film left on the surface which will depend on the end use of the patterned substrate. For example the functional groups may act as conductive moieties or they may be chosen to interact with specific analytes in for sensor applications of the patterned substrate. The organic molecules can also be so designed such that they are conducting, semiconducting or insulating. As such, when the present invention is applied for the formation of patterned SAMs with these molecules, the patterned SAMs can directly function as device elements in a nanometer scale.

Thus, in one embodiment of the method, once the monolayer has been deposited, depending on the self-assembling molecule, it may be desirable to functionalize the molecules forming the self-assembled monolayer with pre-selected moieties. For example, the monolayer may be functionalized as a means of preparing it to receive another coating so that that monolayer acts as an intermediate layer between the surface and the additional coating. One such example would be to provide a “conversion coating” of a metal onto which another hydrophilic coating, e.g. epoxy paint is applied. Another would be a graft between a metal and a cement or adhesive such as is used to anchor dental amalgams. Such intermediate layers would provide a bond whose energy is strong, single functioned and well characterized, in contrast to the poorly understood reaction mechanisms which are found in the coatings industries today.

Further, the method of the present invention is not restricted to patterning a silicon surface, for example other materials may be used as substrates so long as self-assembled monolayers can be produced on them with the organic molecules having the polar head as discussed above (exemplified by organophosphonic acid molecules). For example the present invention may be used with substrates such as, but not limited to aluminum, iron, Si, TiO₂, GaAs, Al₂O₃, ZnO, Ge, ITO, and binary, ternary and quaternery compounds of Ga, In, As, Al and P in various combinations. The requirement is that the substrate has a hydrophilic surface which is the case with metals that form natural oxide protective layers. Conducting polymers such as polyacetylene, polypyrrole, polyaniline, and their derivatives can also be used as a substrate as long as their surface is hydrophilic or can be rendered hydrophilic via surface treatments such as UV/ozone treatment (see reference 21). While the present invention has been described with what are presently considered to be the preferred embodiments, the claims are not to be limited to the disclosed embodiments. To the contrary, the claims are intended to cover various modifications and equivalent structures and functions as are apparent from the appended claims. One of skill in the art may alter the described examples, and reasonable modifications and variations are possible from the foregoing disclosure without departing from either the spirit or scope of the present invention.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

### REFERENCES CITED

(1) C. F. Quate, “Scanning probes as a lithography tool for nanostructures”, Surf. Sci. 386, 259-264 (1997).
(2) R. M. Nyffenegger and R. M. Penner, “Nanometer-scale surface modification using the scanning probe lithography microscope: progress since 1991”, Chem. Rev. 97, 1195-230 (1997).
(3) S. Kraemer, R. R. Fuierer, and C. B. Gorman, “Scanning probe lithography using self-assembled monolayers. Chem. Rev. 103, 4367-4418 (2003).
(4) B. D. Gates, Q. B. Xu, J. C. Love, D. B.Wolfe, and G. M. Whitesides, “Unconventional nanofabrication”, Annu. Rev. Mater. Res. 34, 339-372 (2004).
(5) H. Sugimura, K. Okiguchi, and N. Nakagiri, “Scanning probe lithography using a trimethylsilyl organosilane monolayer resist”, Jpn. J. Appl: Phys. 35, 3749-3753 (1996).
(6) S. C. Minne, H. T. Soh, P. Flueckiger, and C. F. Quate, “Fabrication of 0.1 micron metal-oxide-semiconductor filed-effect transistors with the atomic force microscopy”, Appl. Phys. Lett. 66, 703-705 (1995).
(7) E. S. Snow and P. M. Campbell, “AFM fabrication of sub-10nanometer metal-oxide devices with in-situ control of electrical-properties”, Science 270, 1639-1641 (1995).
(8) P. Avouris, R. Martel, T. Hertel, and R. Sandstrom, “AFM-tip-induced and current-induced local oxidation of silicon and metals”, Appl. Phys. A 66, S659-S667 (1998).
(9) M. Sigrist, A. Fuhrer, T. Ihn, K. Ensslin, D. C. Driscoll, and A. C. Gossard “Multiple layer local oxidation for fabricating semiconductor nanostructures”, Appl. Phys. Lett. 85, 3558-3560 (2004).
(10) Z. Y. Shen, S. M. Hou, H. Sun, X. Y. Zhao, and Z. Q. Xue, “Local oxidation of titanium thin films using an atomic force microscope under static and pulsed voltages”, J. Phys. D: Appl. Phys. 37, 1357-1361 (2004).
(11) H. Sugimura, K. Okiguchi, and N. Nakagiri, “Nanoscale patterning of an organosilane monolayer on the basis of tip-induced electrochemistry in atomic force microscopy”, J. Vac. Sci. Technol. B 14, 4140-4143 (1996).
(12) H. Sugimura, T. Hanji, K. Hayashi, and O. Takai, “Surface potential nanopatterning combining alkyl and fluroalkylsilane self-assembled monolayers fabricated via scanning probe lithography”, Adv. Mater. 14, 524-526 (2002).
(13) R. Maoz, S. R. Cohen, and J. Sagiv, “Nanoelectrochemical Patterning of Monolayer Surfaces: Toward Spatially Defined Self-Assembly of Nanostructures”, Adv. Mater. 11, 55-61 (1999).
(14) R. Maoz, E. Frydman, S. R. Cohen, and J. Sagiv, “Constructive Nanolithography: Inert Monolayers as Patternable Templates for In-Situ Nanofabrication of Metal-Semiconductor-Organic Surface Structures-A Generic Approach”, Adv. Mater. 12, 725-731 (2000).
(15) S. Hong, J. Zhu, and C. A. Mirkin, “Multiple ink nanolithography: toward a multiple-pen nano-plotter”, Science 286, 523-525 (1999).
(16) P. E. Sheehan, L. J. Whitman, W. P. King, B. A. Nelson, “Nanoscale deposition of solid inks via thermal dip pen nanolithography”, Appl. Phys. Lett. 85, 1589-1591 (2004).
(17) G.-Y. Liu, S. Xu, Y. Qian, “Nanofabrication of self-assembled monolayers using scanning probe lithography”, Acc. Chem. Res. 33, 457-466 (2000).
(18) R. W. Carpick and M. Salmeron, “Scratching the surface: Fundamental investigations of tribology with atomic force microscopy”, Chem. Rev. 97, 1163-1194 (1997).
(19) H.-Y. Nie, D. J. Miller, J. T. Francis, M. J. Walzak and N. S. Mcintyre, “Robust self-assembled octadecylphosphonic acid monolayers on a mica substrate”, Langmuir 21, 2773-2778 (2005).
(20) H.-Y. Nie, M. J. Walzak, and N. S. McIntyre, “Delivering Octadecylphosphonic Acid Self-Assembled Monolayers on a Si Wafer and Other Oxide Surfaces”, J. Phys. Chem. B, 110, pp. 21101-21108 (2006)
(21) H.-Y. Nie, M. J. Walzak, B. Berno, and N. S. McIntyre, “Atomic force microscopy study of polypropylene surfaces treated by UV and ozone: modification of morphology and adhesion force”, Appl. Surf. Sci. 144-145, 627-632 (1999).

Therefore what is claimed is:

1. A method of selectively removing organic molecules from a self-assembled film of such organic molecules on a substrate having a hydrophilic surface, comprising:
applying a first bias potential to a substrate having a hydrophilic surface and a self-assembled film of organic molecules located on the hydrophilic surface, the organic molecules having a polar headgroup attached to an aromatic or aliphatic hydrocarbon structure; and
applying a second bias potential to a conductive probe tip wherein said second bias potential is more positive than said first bias potential such that a potential difference between said first and second potentials is greater than a threshold voltage above which organic molecules adjacent to the conductive probe tip are removed.

2. The method according to claim 1 wherein the conductive probe tip is scanned over the surface in a pattern leaving behind a pattern of removed organic molecules.

3. The method according to claim 1 wherein said substrate is held at electrical ground potential and said conductive probe tip is held at a positive potential.

4. The method according to claim 1 wherein said substrate is held at a negative electrical potential and said conductive probe tip is held at electrical ground potential.

5. The method according to claim 1 wherein the potential difference provides an electric field strength ranging from about 10⁸ to about 10¹⁰ V/m across the monolayer film.

6. The method according to claim 1 wherein the potential difference provides an electric field of about 10⁹ V/m across the monolayer film.

7. The method according to claim 1 wherein said the potential difference is in a range from about 1 V to about 50 V.

8. The method according to claim 7 wherein said the potential difference is in a range from about 4 to about 20 V.

9. The method according to claim 1 wherein said substrate is silicon, and said hydrophilic surface is silicon oxide.

10. The method according to claim 1 wherein said substrate is any one of Si, Al, Fe, TiO₂, GaAs, ZnO, Ge, and ITO, conducting polymers, binary, ternary and quaternery compounds of Ga, In, As, Al and P and combinations thereof.

11. The method according to claim 1 wherein said organic molecules having a polar headgroup attached to an aromatic or aliphatic hydrocarbon structure are selected from the group consisting of organophosphonic acid molecules, alkylphosphonic acids and derivatives thereof, aromatic-phosphonic acid and derivatives, fluorinated alkylphosphonic acids and derivatives thereof, organic silanes and derivatives thereof, and combinations thereof.

12. The method according to claim 11 wherein organophosphonic acid molecules are selected from the group consisting of octadecylphosphonic acid and derivatives thereof, dodecylphosphonic acid and derivatives thereof, pyrylphosphonic acid and derivatives thereof, and
nonacosafluorohexadecylphosphonic acid and derivatives thereof, and wherein said organic silane is octadecyltrichlorosilane.

13. The method according to claim 1 wherein said conductive probe tip is maintained in contact with the monolayer film or maintained at a distance from said monolayer film surface such that the threshold voltage is reached.

14. The method according to claim 1 performed in an environment with a relative humidity in a range from about 10% to about 90% at room temperature.

15. The methods according to claim 1 performed in a gaseous environment under a relative humidity in a range from about 10 to about 90% and at a temperature in a range from room temperature to about 80° C.

16. The methods according to claim 15 wherein gaseous environment is air.

17. The method according to claim 10 wherein said substrate is a conducting polymer selected from the group consisting of polyacetylene, polypyrrole and polyaniline, said conducting polymer having a surface modified to render it hydrophilic.

18. A method of patterning a substrate having a hydrophilic surface having a self-assembled film of organic molecules on said hydrophilic surface, comprising the steps of:
a) treating a surface of a substrate having a hydrophilic surface to remove impurities therefrom; and
b) exposing the hydrophilic surface to a fluid comprising a mixture of organic molecules which can self-assemble on the hydrophilic surface and hydrophobic molecules, the organic molecules being comprised of a polar headgroup attached to an aromatic or aliphatic hydrocarbon structure;
c) applying a first bias potential to the substrate;
d) applying a second bias potential to a conductive probe tip wherein said second bias potential is more positive than said first bias potential such that a potential difference between said first and second potentials is greater than a threshold voltage above which organic molecules are removed below the conductive probe tip; and
e) scanning said conductive probe in a pattern over the surface of the substrate in close proximity to the surface leaving behind said pattern of removed organic molecules.

19. The method according to claim 18 wherein said substrate is held at electrical ground potential and said conductive probe tip is held at a positive potential.

20. The method according to claim 18 wherein said substrate is held at a negative electrical potential and said conductive probe tip is held at electrical ground potential.

21. The method according to claim 18 wherein the potential difference provides an electric field strength ranging from about 10⁸ to about 10¹⁰ V/m across the monolayer film.

22. The method according to claim 18 wherein the potential difference provides an electric field of about 10⁹ V/m across the monolayer film.

23. The method according to claim 18 wherein said the potential difference is in a range from about 1 V to about 50 V.

24. The method according to claim 23 wherein said the potential difference is in a range from about 4 to about 20 V.

25. The method according to claim 18 wherein said substrate is silicon, and said hydrophilic surface is silicon oxide.

26. The method according to claim 18 wherein said substrate is any one of Si, Al, Fe, TiO₂, GaAs, ZnO, Ge, ITO, conducting polymers, binary, ternary and quaternery compounds of Ga, In, As, Al and P and combinations thereof.

27. The method according to claim 26 wherein said substrate is a conducting polymer selected from the group consisting of polyacetylene, polypyrrole and polyaniline, said conducting polymer having a surface modified to render it hydrophilic.

28. The method according to claim 18 wherein said organic molecules having a polar headgroup attached to an aromatic or aliphatic hydrocarbon structure are selected from the group consisting of organophosphonic acid molecules, alkylphosphonic acids and derivatives thereof, aromatic-phosphonic acid and derivatives, fluorinated alkylphosphonic acids and derivatives thereof, organic silanes and derivatives thereof, and combinations thereof.

29. The method according to claim 28 wherein organophosphonic acid molecules are selected from the group consisting of octadecylphosphonic acid and derivatives thereof, dodecylphosphonic acid and derivatives thereof, pyrylphosphonic acid and derivatives thereof, and
nonacosafluorohexadecylphosphonic acid and derivatives thereof, and wherein said organic silane is octadecyltrichlorosilane.

30. The method according to claims 18 wherein said conductive probe tip is maintained in contact with the monolayer film or maintained at a distance from said monolayer film surface such that the threshold voltage is reached.

31. The method according to claim 18 performed in an environment with a relative humidity in a range from about 10 to about 90% at room temperature.

32. The methods according to claim 18 performed in a gaseous environment under a relative humidity in a range from about 10 to about 90% and at a temperature in a range from room temperature to about 80° C.

33. The methods according to claim 32 wherein gaseous environment is air.
